(19) United States
(12) Patent Application Publication
(10) Pub. No.: US 2006/0031742 A1
(43) Pub. Date: Feb. 9, 2006

(54) Decoding device and decoding method

(75) Inventors: Toshihiko Fukuoka, Osaka (JP); Hiroyuki Senda, Kyotanabe-shi (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd., Osaka (JP)

(21) Appl. No.: 11/244,187

(22) Filed: Oct. 6, 2005

Related U.S. Application Data
(62) Division of application No. 10/239,953, filed on Sep. 27, 2002.

(30) Foreign Application Priority Data
Mar. 27, 2000 (JP) 2000-86831
Mar. 27, 2001 (WO) PCT/JP01/02522

(51) Int. Cl. H03M 13/00

(52) U.S. Cl. 714/784

(57) ABSTRACT

Improper correction is avoided in decoding of an extended Reed-Solomon code. The decoding device includes: a syndrome computation section for computing input data syndromes from input data and corrected data syndromes from first corrected data obtained from the input data; an evaluator/locator polynomial deriving section for outputting coefficients at each order of an error evaluator polynomial and an error locator polynomial obtained based on the input data syndromes, as well as error magnitudes; a Chien search section for outputting roots of the error locator polynomial; and an error correction section for outputting data obtained by performing error correction for the input data when the input data has an error while otherwise outputting the input data, as the first corrected data, and also outputting the input data obtained by restoration when the first corrected data has an error while otherwise outputting the first corrected data, as second corrected data.

### TECHNICAL FIELD

The present invention relates to a decoding technology of performing multiple error correction for an extended Reed-Solomon code.

### BACKGROUND ART

Reed-Solomon codes have been extensively used as codes allowing multiple error correction in the occasions of storage of information in various mass-storage devices, transmission of information in high-speed communications and the like.

A Reed-Solomon code, which is one type of block error correcting code, is a code in a Galois field of which the primitive element is α when α is the root of W(z)=0 where W(z) is a primitive polynomial. Consider a Reed-Solomon code having roots in elements α⁰, α¹, . . . , αˆ (2^{m}−2) of a Galois field GF(2^{m}) of which the primitive element is α. This code has a code length n=2^{m}−1, and m bits constitute one processing unit, that is, one symbol. The amount of original information is n−2t symbols (t is the number of error corrections).

In general, the decoding of a Reed-Solomon code is carried out following the procedure of:

(a) computing syndromes,

(b) computing an error evaluator polynomial and an error locator polynomial,

(c) computing error locations by Chien search,

(d) computing error magnitudes, and

(e) correcting data based on the error locations and the error magnitudes.

Details of this decoding method are disclosed in Japanese Laid-Open Patent Publication No. 10-135846.

In recent years, in systems of cable modems, cable television and the like, specifications using an extended Reed-Solomon code for error correction have been adopted. An extended Reed-Solomon code is a code having a code length n equal to or more than the number of elements q of a Galois field from which roots of the code originate. The code is called a singly extended Reed-Solomon code when the code length n=q, and a doubly extended Reed-Solomon code when the code length n=q+1.

For example, in a cable television system in North America, adopted is a singly extended Reed-Solomon code having the number of error corrections t=3, in which in a Galois field GF(2⁷), a primitive polynomial P(x)=x⁷+x³+1 and a generator polynomial G_{L}(x)=(x+α) (x+α²) (x+α³) (x+α⁴) (x+α⁵) are used. In this extended Reed-Solomon code, the generator polynomial G_{L}(x) is a fifth-order polynomial although the number of error corrections t=3. This requires processing different from normal one during syndrome computation.

A normal Reed-Solomon code must be configured in a Galois field GF(2^{m+1}) having 2^{m+1} elements when it is intended to have a code length n of 2^{m}. However, an extended Reed-Solomon code is allowed to have a code length n of 2^{m} or more even when it is configured in a Galois field GF(2^{m}).

### PROBLEM TO BE SOLVED

Consider a Reed-Solomon code in a Galois field GF(2⁷) having the number of bits per symbol m=7 and the number of error corrections t=3.

If a normal Reed-Solomon code is considered, it has its roots in elements α⁰, α¹, . . . , α¹²⁶ of the Galois field GF(2⁷) and a code length n=127. Since the order of a generator polynomial G(x) is double the number of error corrections t and the number of error corrections t=3, the generator polynomial G(x) can be expressed as a sixth-order polynomial G(x)=(x+α) (x+α²) (x+α³) (x+α⁴) (x+α⁵) (x+α⁶).

If an extended Reed-Solomon code is considered, it is possible to configure a code having a larger code length in the same Galois field GF(2⁷) for error correction. For example, it is possible to consider an extended Reed-Solomon code having a code length n=128.

In decoding of a normal Reed-Solomon code, since the roots of an error locator polynomial have one-to-one correspondence with error locations. Therefore, the error locations are determined by solving the error locator polynomial by Chien search. The Chien search is a method in which all elements of a Galois field are sequentially substituted in an error locator polynomial and elements of which substitution makes the value of the polynomial zero are determined as roots of the error locator polynomial. For example, when the number of error corrections t=3, the elements are sequentially substituted in a third-order error locator polynomial, and elements of which substitution makes the value of the polynomial zero are determined as three roots of the error location polynomial.

If errors exceeding the correction ability are added to a codeword, an error evaluator polynomial and an error locator polynomial fail to be derived correctly or roots of the error locator polynomial fail to be derived correctly by Chien search. By these failures, inability of error correction is recognized. In this event, input data is output as it is without execution of error correction.

However, in an extended Reed-Solomon code, since the code length n is larger than the number of elements of the Galois field GF(2⁷) other than 0, no one-to-one correspondence is established between the elements and the error locations. Therefore, in the Chien search, processing different from that in decoding of a normal Reed-Solomon code must be performed.

In view of the above, an extended Reed-Solomon code is decoded under the following presumption. An extended Reed-Solomon code having a code length n=128, for example, is composed of 122 information symbols and 6 redundant symbols when the number of error corrections is 3. In the Galois field GF(2⁷), only 127 symbols can be corrected by Chien search. Therefore, only 127 symbols among the 128 symbols of the received word excluding one redundancy symbol are subjected to error correction.

However, the above method has a problem that improper correction may occur because 127 symbols of a code composed of 128 symbols are corrected by using the code and an error may be generated for the one redundant symbol that is not subjected to correction.

### DISCLOSURE OF THE INVENTION

An object of the present invention is providing a decoding device and a decoding method in which whether or not error correction is possible for a received word of an extended Reed-Solomon code is decided during decoding of the word, and properly corrected data is obtained when error correction is possible while improper correction is avoided when error correction is not possible.

The decoding device in the first aspect of the invention includes a correction processing section for performing error correction for a received word made of an extended Reed-Solomon code to determine corrected data, wherein the correction processing section decides whether or not the generated corrected data has an error based on syndromes of the corrected data, and the correction processing section outputs the corrected data when errorless corrected data is generated, while outputting the received word before the error correction when errorless corrected data fails to be generated.

According to the decoding device described above, when failure to generate errorless corrected data is finally decided, output of the non-properly corrected data is avoided.

In the decoding device described above, the correction processing section preferably decides that errorless corrected data fails to be generated when the corrected data generated from the received word has an error.

With the above configuration, when the corrected data has an error, failure to generate errorless corrected data is determined without further execution of error correction, and the received word before the error correction is output.

In the decoding device described above, preferably, the correction processing section executes the error correction repeatedly until errorless corrected data is generated, and decides that errorless corrected data fails to be generated when no errorless corrected data is generated after execution of the error correction a plurality of times.

With the above configuration, the possibility of generating errorless corrected data increases by the repeated error correction.

The decoding device in the second aspect of the present invention includes: a syndrome computation section for receiving a received word made of an extended Reed-Solomon code as input data, computing syndromes for the input data as input data syndromes, and outputting a first flag signal indicating whether or not the input data has an error that is determined based on the input data syndromes, while computing syndromes for first corrected data obtained based on the input data as corrected data syndromes and outputting a second flag signal indicating whether or not the first corrected data has an error that is determined based on the corrected data syndromes; an evaluator/locator polynomial deriving section for computing coefficients at each order of an error evaluator polynomial and an error locator polynomial based on the input data syndromes, and computing error magnitudes based on error evaluation values and corresponding error locator polynomial differential values both obtained from the coefficients; a Chien search section for determining roots of the error locator polynomial based on the coefficients, and computing the error evaluation values by substituting the roots in the error evaluator polynomial and the error locator polynomial differential values by substituting the roots in a derivative of the error locator polynomial; and an error correction section for outputting data obtained by performing the error correction for the input data based on the roots and the corresponding error magnitudes as the first corrected data when the first flag signal indicates that the input data has an error, while outputting the input data as the first corrected data when the first flag signal indicates that the input data has no error, the error correction section outputting data obtained by performing restoration for the first corrected data to restore the data before the error correction as second corrected data when the second flag signal indicates that the first corrected data has an error, while outputting the first corrected data as the second corrected data when the second flag signal indicates that the first corrected data has no error.

According to the decoding device described above, not only the input data syndromes but also the corrected data syndromes are obtained. This makes it possible to determine whether or not the error correction has been executed properly.

In the decoding device described above, preferably, the syndrome computation section includes: a selector for receiving and alternately outputting the input data and the first corrected data output from the error correction section; a syndrome operator for computing the input data syndromes and the corrected data syndromes based on the input data and the first corrected data output from the selector; an input data syndrome holder for holding and outputting the input data syndromes; a corrected data syndrome holder for holding and outputting the corrected data syndromes; a first zero syndrome detector for outputting the first flag signal indicating that the input data has no error when all the input data syndromes output from the input data syndrome holder are zero and otherwise indicating that the input data has an error; and a second zero syndrome detector for outputting the second flag signal indicating that the first corrected data has no error when all the corrected data syndromes output from the corrected data syndrome holder are zero and otherwise indicating that the first corrected data has an error.

With the above configuration, the input data syndromes and the corrected data syndromes are obtained in parallel, and the first and second flag signals are output simultaneously. Therefore, whether or not the input data and the first corrected data have an error can be determined simultaneously.

In the decoding device described above, preferably, the evaluator/locator polynomial deriving section determines coefficients at each order of the error evaluator polynomial and the error locator polynomial based on the input data syndromes by Euclidean algorithm operation and outputs the computed coefficients, and the evaluator/locator polynomial deriving section outputs the coefficients even when the order of the error locator polynomial is equal to or less than the order of the error evaluator polynomial at the completion of the Euclidean algorithm operation.

With the above configuration, the error evaluator polynomial and the error locator polynomial can be obtained irrespective of the results of the Euclidean algorithm operation. Therefore, the error locations and the error magnitudes can be determined for decoding of the extended Reed-Solomon code.

In the decoding device described above, preferably, the Chien research section sequentially substitutes elements of a Galois field in which roots of the extended Reed-Solomon code are defined in the error locator polynomial to determine elements of which substitution makes the value of the error locator polynomial zero as the roots of the error locator polynomial, and the Chien research section outputs the roots of the error locator polynomial even when the number of different roots of the error locator polynomial is less than the order of the error locator polynomial.

With the above configuration, the different roots of the error locator polynomial obtained by Chien search can be used irrespective of the number of the roots. Therefore, the error locations and the error magnitudes can be determined for decoding of the extended Reed-Solomon code.

In the decoding device described above, preferably, the error correction section includes: a first error corrector for outputting data obtained by performing the error correction for the input data when the first flag signal indicates that the input data has an error, the error correction including subtracting the corresponding error magnitude from a symbol indicated by the error location corresponding to each of the roots, while otherwise outputting the input data as the first corrected data; an error location data holder for holding and outputting the error locations; an error magnitude data holder for holding and outputting the error magnitudes; and a second error corrector for outputting data obtained by performing the restoration for the first corrected data to restore the data before the error correction when the second flag signal indicates that the first corrected data has an error, the restoration including adding the corresponding error magnitude to a symbol indicated by the error location, while otherwise outputting the first corrected data as the second corrected data.

With the above configuration, the correction of the input data and the restoration for the first corrected data can be performed in parallel. Therefore, high-speed processing is possible.

Preferably, the decoding device described above further includes a data storage section for holding the input data until the error correction section starts determining the first corrected data and then outputting the input data, and holding the first corrected data until the error correction section starts determining the second corrected data and then outputting the first corrected data.

With the above configuration, data required for the error correction section can be supplied at appropriate timings. In addition, it is only necessary to store either the input data or the first corrected data generated from the input data for one received word. Therefore, the capacity of the data storage section can be reduced.

The decoding method in the third aspect of the invention includes a correction processing step of performing error correction for a received word made of an extended Reed-Solomon code to determine corrected data, wherein the correction processing step includes deciding whether or not the generated corrected data has an error based on syndromes of the corrected data, and when errorless corrected data is generated, the generated corrected data is determined as the corrected data to be obtained, while when errorless corrected data fails to be generated, the received word before the error correction is determined as the corrected data to be obtained.

In the decoding method described above, preferably, in the correction processing step, failure of generation of errorless corrected data is decided when the corrected data generated from the received word has an error.

In the decoding method described above, preferably, in the correction processing step, the error correction is executed repeatedly until errorless corrected data is generated, and failure of generation of errorless corrected data is decided when no errorless corrected data is generated after execution of the error correction a plurality of times.

### EFFECT OF THE INVENTION

According to the decoding device and the decoding method of the present invention, error-corrected data is subjected to syndrome computation again for error detection. Therefore, improper correction can be prevented, and thus decoding of not only a normal Reed-Solomon code but also an extended Reed-Solomon code can be realized.

### BRIEF DESCRIPTION OF THE DRAWINGS

FIG. 1 is a block diagram of a Reed-Solomon decoding device of an embodiment of the present invention.

FIG. 2 is a flowchart of processing performed by the Reed-Solomon decoding device of FIG. 1.

FIG. 3 is a block diagram of a syndrome computation section in FIG. 1.

FIG. 4 is a block diagram of an error correction section in FIG. 1.

FIG. 5 is a timing chart illustrating operation of the Reed-Solomon decoding device of FIG. 1.

FIG. 6 is a timing chart illustrating internal operation of the syndrome computation section of FIG. 3.

### BEST MODE FOR CARRYING OUT THE INVENTION

Hereinafter, a preferred embodiment of the present invention will be described with reference to the accompanying drawings.

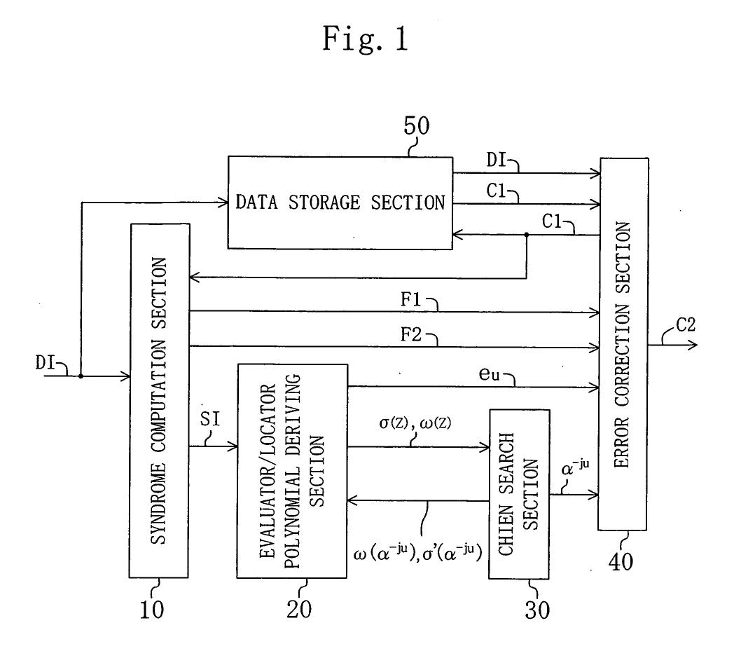

FIG. 1 is a block diagram of a Reed-Solomon decoding device of an embodiment of the present invention. The Reed-Solomon decoding device of FIG. 1 includes a syndrome computation section 10, an evaluator/locator polynomial deriving section 20, a Chien search section 30, an error correction section 40 and a data storage section 50. The syndrome computation section 10, the evaluator/locator polynomial deriving section 20, the Chien search section 30 and the error correction section 40 constitute a correction processing section.

The Reed-Solomon decoding device of FIG. 1 receives a word composed of an extended Reed-Solomon code as input data DI, decodes the input data DI, and outputs the resultant data as second corrected data C2. Hereinafter, assume as an example that the input extended Reed-Solomon code is a singly extended Reed-Solomon code in a Galois field GF(2⁷) in which the number of bits per symbol m=7 and the code length n=128. One received word is composed of 128 symbols. Assume also that the number of error corrections t=3. This extended Reed-Solomon code therefore allows error correction of 3 symbols.

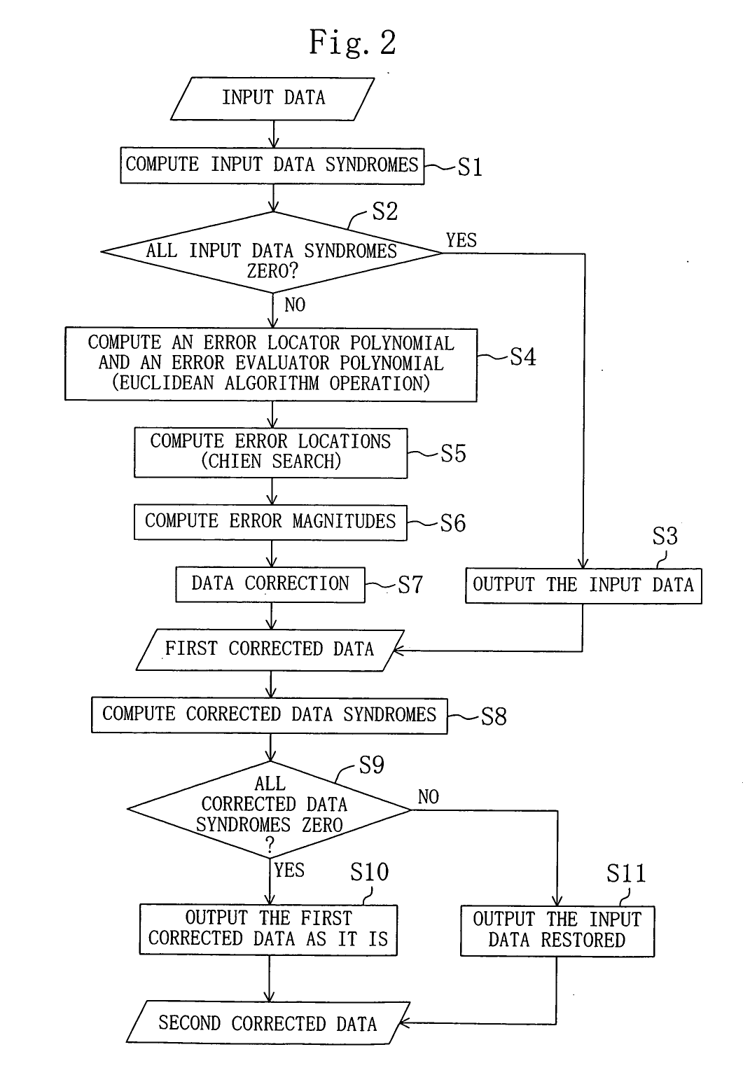

FIG. 2 is a flowchart of processing performed by the Reed-Solomon decoding device of FIG. 1. Hereinafter, the processing will be described with reference to FIG. 1 and steps S1 to S11 in FIG. 2. Assume that an error having a magnitude of eᵤ has occurred in the symbol at a location ju in the received word, where u=1, 2, . . . , k (k≦t). The location ju of the symbol having an error in a received word is herein called the error location.

Input data DI is input into the syndrome computation section 10 and the data storage section 50. The data storage section 50 stores the input data DI and then outputs the data to the error correction section 40.

In step S1, the syndrome computation section 10 computes syndromes of the input data DI as input data syndromes SI.

In step S2, the syndrome computation section 10 detects whether or not all the input data syndromes SI are zero. If all the input data syndromes SI are zero, the syndrome computation section 10 decides that the input data DI has no error, and asserts a first non-error state indication signal F1 as a first flag signal that is output to the error correction section 40. The process then proceeds to step S3. If there is a non-zero input data syndromes SI, the syndrome computation section 10 decides that the input data DI has an error, and negates the first non-error state indication signal F1 that is output to the error correction section 40. In this case, the process proceeds to step S4. In either case, the syndrome computation section 10 outputs the input data syndromes SI to the evaluator/locator polynomial deriving section 20.

In step S3, receiving the asserted first non-error state indication signal F1 indicating that no error correction is necessary, the data correction section 40 outputs the input data DI received from the data storage section 50 to the syndrome computation section 10 and the data storage section 50 as it is as first corrected data C1.

Processing in steps S4 through S7 is performed when the first non-error state indication signal F1 is negated indicating that the input data DI has an error.

In step S4, the evaluator/locator polynomial deriving section 20 computes coefficients at each order of an error locator polynomial σ(z) and an error evaluator polynomial ω(z) from the input data syndromes SI by Euclidean algorithm operation, and outputs the resultant coefficients of the polynomials to the Chien search section 30.

The evaluator/locator polynomial deriving section 20 includes a data holder (not shown) and a Galois operator (not shown). The data holder holds the input data syndromes SI and intermediate results of Euclidean algorithm operation, and finally outputs the coefficients at each order of the error locator polynomial σ(z) and the error evaluator polynomial ω(z). The Galois operator executes Euclidean algorithm operation for the output from the data holder to obtain the intermediate results and sends the intermediate results to the data holder. Details of the Euclidean algorithm operation are disclosed in Japanese Laid-Open Patent Publication No. 10-135846.

Note that the evaluator/locator polynomial deriving section 20 in FIG. 1 outputs the coefficients of the polynomials even when the order of the error locator polynomial σ(z) is equal to or less than the order of the error evaluator polynomial ω(z) at the completion of the Euclidean algorithm operation.

In step S5, the Chien search section 30 performs Chien search to determine roots α^{-ju} of the error locator polynomial σ(z). More specifically, the Chien search section 30 sequentially substitutes the elements of the Galois field GF(2⁷) in the error locator polynomial σ(z), determines the elements of which substitution makes the value of the error locator polynomial σ(z) zero as the roots α^{-ju} of the error locator polynomial σ(z), and outputs the roots to the error correction section 40. During this operation, the Chien search section 30 does not make decision on whether or not error correction is possible even when the number of different roots of the error locator polynomial σ(z) in the Galois field GF(2⁷) is less than the order of the error locator polynomial σ(z), and outputs the roots α^{-ju} to the error correction section 40. The error locations ju correspond to the respective roots α^{-ju} of the error locator polynomial σ(z).

In addition, the Chien search section 30 substitutes the respective roots α^{-ju} of the error locator polynomial σ(z) in the error evaluator polynomial ω(z) to obtain respective error evaluation values ω(α^{-ju}), and also substitutes the respective roots α^{-ju} of the error locator polynomial σ(z) in a derivative of the error locator polynomial σ(z) to obtain error locator polynomial differential values σ′(α^{-ju}). The Chien search section 30 outputs the error evaluation values ω(α^{-ju}) and the error locator polynomial differential values σ′(α^{-ju}) to the evaluator/locator polynomial deriving section 20.

In step S6, the Galois operator (not shown) of the evaluator/locator polynomial deriving section 20 divides each of the error evaluation values ω(α^{-ju}) by the corresponding error locator polynomial differential value σ′(α^{-ju}) to obtain an error magnitude eᵤ indicating the error bit in the symbol at the error location ju, and outputs the results to the error correction section 40.

In step S7, the error correction section 40 performs error correction for the input data DI received from the data storage section 50 based on the error locations ju corresponding to the roots α^{-ju} of the error locator polynomial σ(z) output from the Chien search section 30 and the error magnitudes eᵤ output from the evaluator/locator polynomial deriving section 20. More specifically, the corresponding error magnitude eᵤ is subtracted from the symbol at the error location ju in the received word as the input data DI. Since this is an operation in the extension field of the Galois field GF(2), addition of the error magnitude eᵤ to the symbol is allowed in place of the subtraction.

The error correction section 40 outputs error-corrected data to the syndrome computation section 10 and the data storage section 50 as the first corrected data C1. The data storage section 50 stores the first corrected data C1 and outputs this again to the error correction section 40.

In step S8, the syndrome computation section 10 computes syndromes of the first corrected data C1 as corrected data syndromes SC.

In step S9, the syndrome computation section 10 detects whether or not all the corrected data syndromes SC are zero. If all the corrected data syndromes SC are zero, the syndrome computation section 10 decides that the first corrected data C1 has no error, and asserts a second non-error state indication signal F2 as a second flag signal that is output to the error correction section 40. The process then proceeds to step S10. If there is a non-zero corrected data syndromes SC, the syndrome computation section 10 decides that the first corrected data C1 has an error, and negates the second non-error state indication signal F2 that is output to the error correction section 40. In this case, the process proceeds to step S11.

In step S10, receiving the asserted second non-error state indication signal F2 indicating that the first corrected data C1 has no error, the data correction section 40 outputs the first corrected data C1 received from the data storage section 50 as it is as the second corrected data C2.

In step S11, receiving the negated second non-error state indication signal F2 indicating that the first corrected data C1 has an error, the data correction section 40 restores the input data DI before the correction from the first corrected data C1 received from the data storage section 50 based on the error locations ju corresponding to the roots α^{-ju} of the error locator polynomial σ(z) output from the Chien search section 30 and the error magnitudes eᵤ output from the evaluator/locator polynomial deriving section 20. More specifically, the corresponding error magnitude eᵤ is added to or subtracted from the symbol at the error location ju in the first corrected data C1. The error correction section 40 outputs the restored input data DI as the second corrected data C2.

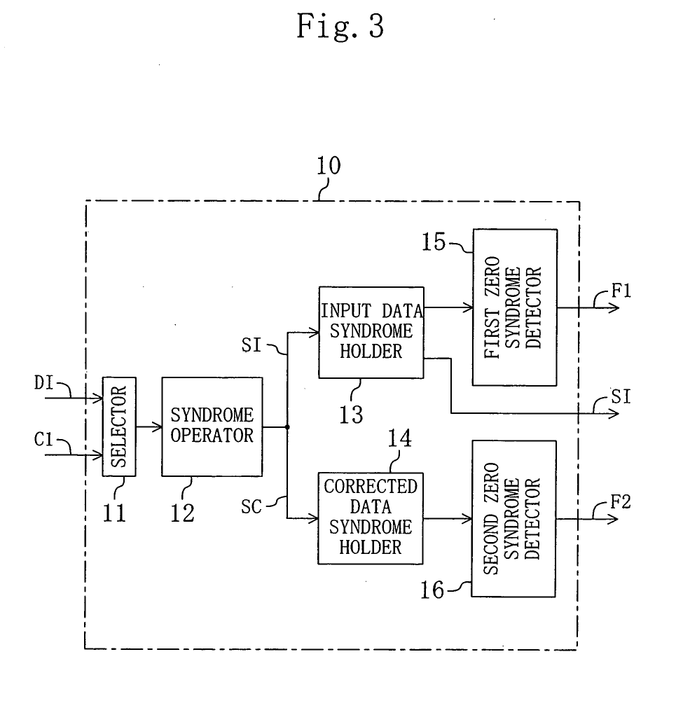

FIG. 3 is a block diagram of the syndrome computation section 10 in FIG. 1. Referring to FIG. 3, the syndrome computation section 10 includes a selector 11, a syndrome operator 12, an input data syndrome holder 13, a corrected data syndrome holder 14, a first zero syndrome detector 15 and a second zero syndrome detector 16.

The selector 11 receives the input data DI and the first corrected data C1 and outputs both the data to the syndrome operator 12 alternately. The syndrome operator 12, operating in synchronization with the selector 11, performs computation for obtaining the input data syndromes SI and computation for obtaining the corrected data syndromes SC alternately, and outputs the computation results to the input data syndrome holder 13 and the corrected data syndrome holder 14, respectively.

The input data syndrome holder 13 receives and holds only the input data syndromes SI from the output of the syndrome operator 12, and then outputs the input data syndromes SI to the first zero syndrome detector 15. When all the input data syndromes SI are zero, the first zero syndrome detector 15 decides that the input data DI has no error and asserts the first non-error state indication signal F1. When there is a non-zero input data syndromes SI, the first zero syndrome detector 15 decides that the input data DI has an error and negates the first non-error state indication signal F1. The signal F1 is output to the error correction section 40. In addition, the input data syndrome holder 13 outputs the input data syndromes SI to the evaluator/locator polynomial deriving section 20 in synchronization with the timing at which the first zero syndrome detector 15 sends the first non-error state indication signal F1.

Likewise, the corrected data syndrome holder 14 receives and holds only the corrected data syndromes SC from the output of the syndrome operator 12, and then outputs the corrected data syndromes SC to the second zero syndrome detector 16. The second zero syndrome detector 16 asserts the second non-error state indication signal F2 when all the corrected data syndromes SC are zero, and negates the second non-error state indication signal F2 when there is a non-zero corrected data syndrome SC. The signal F2 is output to the error correction section 40.

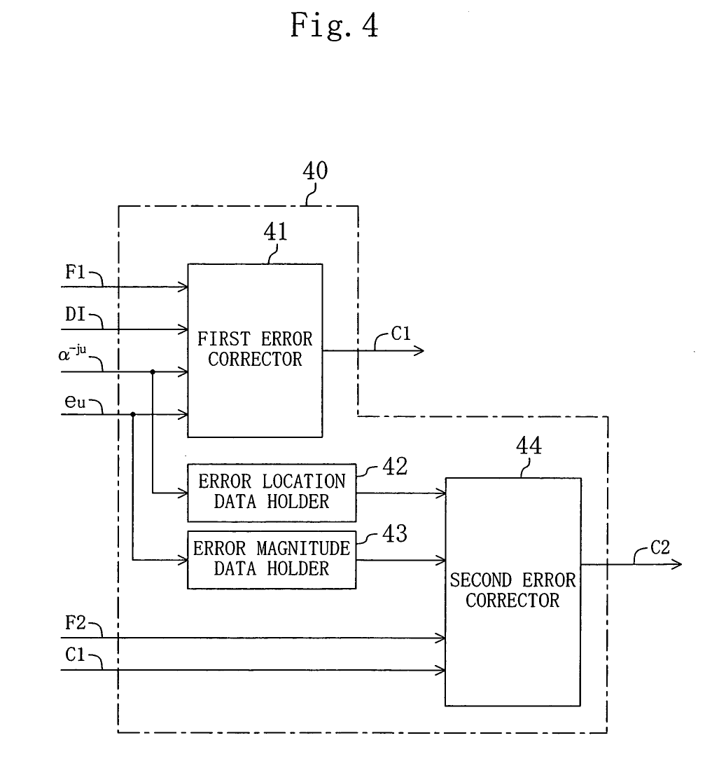

FIG. 4 is a block diagram of an error correction section 40 in FIG. 1. Referring to FIG. 4, the error correction section 40 includes a first error corrector 41, an error location data holder 42, an error magnitude data holder 43 and a second error corrector 44.

The first error corrector 41 receives the first non-error state indication signal F1, the input data DI output from the data storage section 50, the roots α^{-ju} of the error locator polynomial σ(z) output from the Chien search section 30 and the error magnitudes eᵤ output from the evaluator/locator polynomial deriving section 20.

The first error corrector 41 outputs the input data DI as it is as the first corrected data C1 when the first non-error state indication signal F1 is active requiring no error correction for the input data DI. When the first non-error state indication signal F1 is inactive, indicating that the input data DI has an error and error correction is necessary, the first error corrector 41 performs error correction for the input data DI. Specifically, the error magnitudes eᵤ corresponding to the error locations ju, which correspond to the roots α^{-ju}, are subtracted from or added to the symbols of the input data DI indicated by the error locations ju. The first error corrector 41 outputs the corrected data as the first corrected data C1 to the syndrome computation section 10 and the data storage section 50.

The error location data holder 42 stores the roots α^{-ju} and outputs them to the second error corrector 44. The error magnitude data holder 43 stores the error magnitudes eᵤ and outputs them to the second error corrector 44.

The second error corrector 44 receives the second non-error state indication signal F2, the first corrected data C1 output from the data storage section 50, the roots α^{-ju} of the error locator polynomial σ(z) and the error magnitudes eᵤ.

The second error corrector 44 outputs the first corrected data C1 as it is as the second corrected data C2 when the second non-error state indication signal F2 is active requiring no error correction for the first corrected data C1. When the second non-error state indication signal F2 is inactive, indicating that the first corrected data C1 has an error and error correction is necessary, the second error corrector 44 performs restoration of the input data DI before the correction by the first error corrector 41 from the first corrected data C1 based on the error locations ju corresponding to the roots α^{-ju} and the error magnitudes eᵤ. This can be done by adding or subtracting the error magnitudes eᵤ corresponding to the error locations ju to or from the symbols of the first corrected data C1 indicated by the error locations ju. The second error corrector 44 outputs the restored input data DI as the second corrected data C2.

As described above, the second error corrector 44 outputs the restored input data DI, not the first corrected data C1, when the first error corrector 41 fails to correct the input data DI properly resulting in the first corrected data C1 having an error.

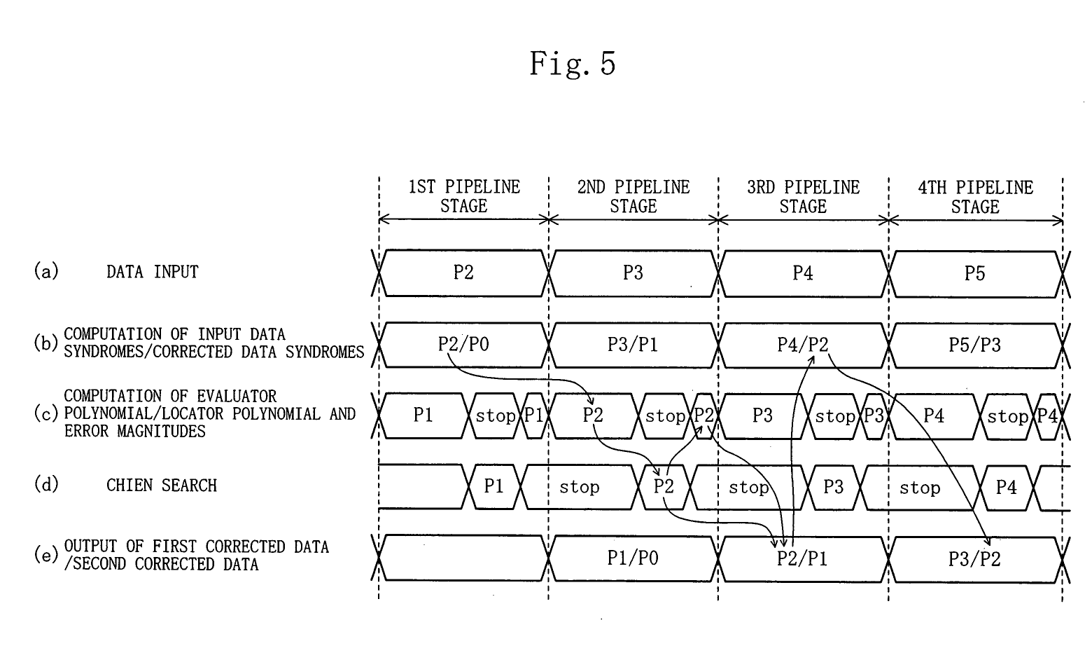

FIG. 5 is a timing chart illustrating operation of the Reed-Solomon decoding device of FIG. 1. In FIG. 5, (a) represents input of the input data DI into the syndrome computation section 10 and the data storage section 50, (b) represents computation of the input data syndromes SI and the corrected data syndromes SC by the syndrome computation section 10, (c) represents computation of the error evaluator polynomial ω(z), the error locator polynomial σ(z) and the error magnitudes eᵤ by the evaluator/locator polynomial deriving section 20, (d) represents Chien search by the Chien search section 30, and (e) represents output of the first and second corrected data C1 and C2 from the error correction section 40.

In FIG. 5, P0 to P5 indicate that tasks related to packets input 0-th to fifth, respectively, are being executed, and stop indicates that the operation is at a stop. One received word having a code length n=128 is handled as one packet. Hereinafter, the operation is described focusing on packet P2, in particular.

In the first pipeline stage, packet P2 is input into the syndrome computation section 10 and the data storage section 50 as the input data DI. The syndrome computation section 10 computes the input data syndromes SI for packet P2 ((a) and (b) in FIG. 5).

In the second pipeline stage, the evaluator/locator polynomial deriving section 20 computes coefficients at each order of the error locator polynomial σ(z) and the error evaluator polynomial ω(z) using the input data syndromes SI for packet P2 computed in the first pipeline stage ((c) in FIG. 5). Thereafter, using the error locator polynomial σ(z) and the error evaluator polynomial ω(z), the Chien search section 30 computes the roots α^{-ju} of the error locator polynomial σ(z), the error evaluation values ω(α^{-ju}) and the error locator polynomial differential values σ′(α^{-ju}) for packet P2 by Chien search ((d) in FIG. 5). Using the error evaluation values ω(α^{-ju}) and the error locator polynomial differential values σ′(α^{-ju}) for packet P2, the evaluator/locator polynomial deriving section 20 computes the error magnitudes eᵤ ((c) in FIG. 5). In the second pipeline stage, one of the evaluator/locator polynomial deriving section 20 and the Chien search section 30 is at rest when the other is under operation.

To enable the above processing, the evaluator/locator polynomial deriving section 20 and the Chien search section 30 receive a clock signal (not shown) having a frequency four times as high as that of a reference clock signal (not shown).

In the third pipeline stage, the error correction section 40 performs error correction for packet P2 as the input data DI held by the data storage section 50, if necessary, using the roots α^{-ju} of the error locator polynomial σ(z) and the error magnitudes eᵤ for packet P2 computed in the second pipeline stage, to obtain the first corrected data C1 ((e) in FIG. 5). The error correction section 40 outputs the first corrected data C1 to the syndrome computation section 10 and the data storage section 50. In the third pipeline stage, also, the syndrome computation section 10 computes the corrected data syndromes SC based on the first corrected data C1 for packet P2. This stage also includes input of packet P4 into the syndrome computation section 10 and the data storage section 50. Therefore, the syndrome computation section 10 also computes the input data syndromes SI for packet P4 ((b) in FIG. 5).

For the parallel computation of the input data syndromes SI and the corrected data syndromes SC, the syndrome computation section 10 receives a clock signal (not shown) having a frequency twice as high as that of the reference clock signal (not shown).

In the fourth pipeline stage, when some of the corrected data syndromes SC of the first corrected data C1 for packet P2 is not zero, the error correction section 40 outputs the input data DI before the correction as the second corrected data C2 by restoring the input data DI from the first corrected data C1 held by the data storage section 50. When all the corrected data syndromes SC are zero, the error correction section 40 outputs the first corrected data C1 held by the data storage section 50 as it is as the second corrected data C2. In this stage, the error correction section 40 also performs error correction for packet P3, which has been input into the syndrome computation section 10 in the second pipeline stage, to obtain the first corrected data C1 for this packet ((e) in FIG. 5).

A series of processing for packet P2 is completed by the four pipeline stages described above. Note that the error correction section 40 and the data storage section 50 receive the reference clock signal (not shown).

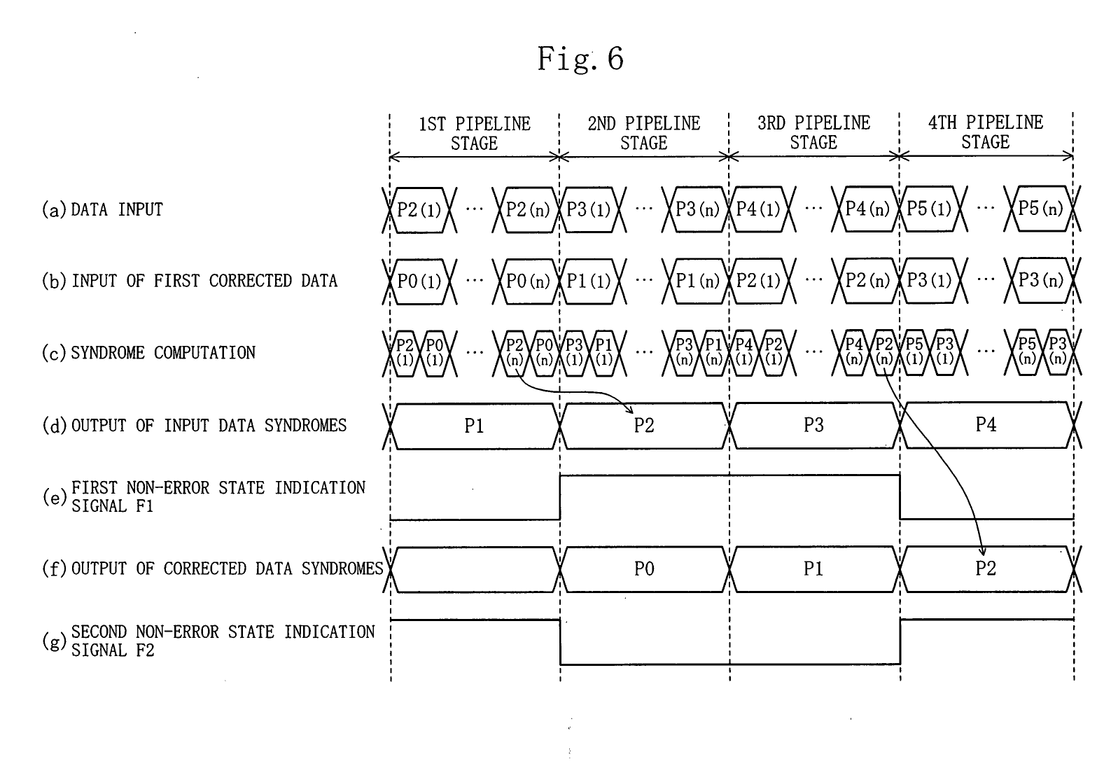

FIG. 6 is a timing chart illustrating internal operation of the syndrome computation section 10 of FIG. 3. In FIG. 6, (a) represents input of the input data DI into the selector 11, (b) represents input of the first corrected data C1 into the selector 11, (c) represents syndrome computation by the syndrome operator 12, (d) represents output of the input data syndromes SI from the input data syndrome holder 13, (e) represents output of the first non-error state indication signal F1 from the first zero syndrome detector 15, (f) represents output of the corrected data syndromes SC from the corrected data syndrome holder 14, and (g) represents output of the second non-error state indication signal F2 from the second zero syndrome detector 16. In FIG. 6, as in FIG. 5, P0 to P5 indicate that tasks related to packets input 0-th to fifth, respectively, are being executed, and P(n) indicates that a task related to the n-th symbol of packet P2 is being executed.

In the first pipeline stage, symbols P2(1), P2(2), . . . , P2(n) of packet P2 as the input data DI are sequentially input into the selector 11 in FIG. 3 ((a) in FIG. 6). Also, symbols P0(1), P0(2), . . . , P0(n) of packet P0 as the first corrected data C1 are sequentially input into the selector 11 ((b) in FIG. 6).

The selector 11 outputs the symbols of packet P2 as the input data DI and the symbols of packet P0 as the first corrected data C1 to the syndrome operator 12 alternately, like P2(1), P0(1), P2(2), P0(2), . . . , P0(n), for example. The syndrome operator 12 performs syndrome computation for the respective symbols received from the selector 11 sequentially in the order of receipt ((c) in FIG. 6). The syndrome operator 12 outputs the input data syndromes SI of the input data DI for packet P2 and the corrected data syndromes SC of the first corrected data C1 for packet P0 to the input data syndrome holder 13 and the corrected data syndrome holder 14, respectively, once the n-th symbols have been computed. The syndrome operator 12 performs the operation of the symbols at a rate double the rate of input of the symbols of the input data DI.

In the second pipeline stage, the input data syndrome holder 13 outputs the input data syndromes SI for packet P2 to the first zero syndrome detector 15 ((d) in FIG. 6). The corrected data syndrome holder 14 outputs the corrected data syndromes SC for packet P0 to the second zero syndrome detector 16 ((f) in FIG. 6). In the second pipeline stage, also, the first zero syndrome detector 15 outputs the results of detection on whether or not all the input data syndromes SI for packet P2 are zero as the first non-error state indication signal F1. For example, when all the input data syndromes SI are zero indicating that packet P2 has no error, the first zero syndrome detector 15 asserts the first non-error state indication signal F1 ((e) in FIG. 6). Likewise, the second zero syndrome detector 16 outputs the results of detection on whether or not all the corrected data syndromes SC for packet P0 are zero as the second non-error state indication signal F2 ((g) in FIG. 6).

In the third pipeline stage, as in the first pipeline stage, the syndrome operator 12 computes the input data syndromes SI for packet P4 and the corrected data syndromes SC for packet P2 ((c) in FIG. 6).

In the fourth pipeline stage, the first zero syndrome detector 15 outputs the results of detection on whether or not all the input data syndromes SI for packet P4 are zero as the first non-error state indication signal F1 ((e) in FIG. 6). The second zero syndrome detector 16 outputs the results of detection on whether or not all the corrected data syndromes SC for packet P2 are zero as the second non-error state indication signal F2 ((g) in FIG. 6). In this way, the syndrome computation section 10 completes the processing for one packet in the four pipeline stages.

As described above, the decoding device of the present invention performs syndrome computation again for the error-corrected data C1 obtained by error-correcting the input data DI, to obtain the corrected data syndromes SC. When the correction is considered improper, the input data before the correction is output. Thus, output of improperly corrected data can be avoided.

In the embodiment described above, error correction is performed once before the decision on whether or not the generated corrected data has an error. The decision may also be made after error correction is performed a plurality of times. In other words, the input data DI may be stored and error correction may be repeated until no error is detected in corrected data. If errorless corrected data is successfully generated, the corrected data may be output. If no errorless corrected data is generated after the repetition of error correction a plurality of times, failure of generation of errorless corrected data is decided, and the stored input data DI as the received word before the correction may be output. Note that, in this case, every time the error correction section 40 outputs corrected data, the syndrome computation section 10 must compute syndromes of the corrected data, decide whether or not the syndromes are zero, notify the error correction section 40 of the results, and output the syndromes to the evaluator/locator polynomial deriving section 20.

The decoding device of the present invention may be implemented by software by use of microprocessors and the like.

### INDUSTRIAL APPLICABILITY

The present invention is useful for decoding of information encoded with an extended Reed-Solomon code.

1-3. (canceled)

4. A decoding device for receiving a received word made of an extended Reed-Solomon code as input data, the device comprising:
an error correction section for determining first corrected data based on the input data;
a syndrome computation section for computing syndromes for the input data as input data syndromes and outputting a first flag signal indicating whether or not the input data has an error that is determined based on the input data syndromes, while computing syndromes for the first corrected data obtained by the error correction section as corrected data syndromes and outputting a second flag signal indicating whether or not the first corrected data has an error that is determined based on the corrected data syndromes;
an evaluator/locator polynomial deriving section for computing coefficients at each order of an error evaluator polynomial and an error locator polynomial based on the input data syndromes, and computing error magnitudes based on error evaluation values and corresponding error locator polynomial differential values both obtained from the coefficients; and
a Chien search section for determining roots of the error locator polynomial based on the coefficients, and computing the error evaluation values by substituting the roots in the error evaluator polynomial and the error locator polynomial differential values by substituting the roots in a derivative of the error locator polynomial,
wherein the error correction section outputs data obtained by performing the error correction for the input data based on the roots and the corresponding error magnitudes as the first corrected data when the first flag signal indicates that the input data has an error, and outputs the input data as the first corrected data when the first flag signal indicates that the input data has no error, to the syndrome computation section, while the error correction section outputs data obtained by performing restoration for the first corrected data to restore the data before the error correction as second corrected data when the second flag signal indicates that the first corrected data has an error, and outputs the first corrected data as the second corrected data when the second flag signal indicates that the first corrected data has no error.

5. The decoding device of claim 4, wherein the syndrome computation section comprises:
a selector for receiving the input data and the first corrected data output from the error correction section and outputting both the data alternately;
a syndrome operator for computing the input data syndromes and the corrected data syndromes based on the input data and the first corrected data output from the selector;
an input data syndrome holder for holding and outputting the input data syndromes;
a corrected data syndrome holder for holding and outputting the corrected data syndromes;
a first syndrome zero detector for outputting the first flag signal indicating that the input data has no error when all components of the input data syndromes output from the input data syndrome holder are zero and otherwise indicating that the input data has an error; and
a second syndrome zero detector for outputting the second flag signal indicating that the first corrected data has no error when all components of the corrected data syndromes output from the corrected data syndrome holder are zero and otherwise indicating that the first corrected data has an error.

6. The decoding device of claim 4, wherein the evaluator/locator polynomial deriving section computes coefficients at each order of the error evaluator polynomial and the error locator polynomial based on the input data syndromes by Euclidean algorithm operation and outputs the computed coefficients, and
the evaluator/locator polynomial deriving section outputs the coefficients even when the order of the error locator polynomial is equal to or less than the order of the error evaluator polynomial at the completion of the Euclidean algorithm operation.

7. The decoding device of claim 4, wherein the Chien research section sequentially substitutes elements of a Galois field in which roots of the extended Reed-Solomon code are defined in the error locator polynomial to determine elements of which substitution makes the value of the error locator polynomial zero as the roots of the error locator polynomial, and
the Chien research section outputs the roots of the error locator polynomial even when the number of different roots of the error locator polynomial is less than the order of the error locator polynomial.

8. The decoding device of claim 4, wherein the error correction section comprises:
a first error corrector for outputting data obtained by performing the error correction for the input data when the first flag signal indicates that the input data has an error, the error correction including subtracting the corresponding error magnitude from a symbol indicated by the error location corresponding to each of the roots, while otherwise outputting the input data as the first corrected data;
an error location data holder for holding and outputting the error locations;
an error magnitude data holder for holding and outputting the error magnitudes; and
a second error corrector for outputting data obtained by performing the restoration for the first corrected data to restore the data before the error correction when the second flag signal indicates that the first corrected data has an error, the restoration including adding the corresponding error magnitude to a symbol indicated by the error location, while otherwise outputting the first corrected data as the second corrected data.

9. The decoding device of claim 4, further comprising a data storage section for holding the input data until the error correction section starts determining the first corrected data for the input data and then outputting the input data to the error correction section, and holding the first corrected data until the error correction section starts determining the second corrected data for the first corrected data and then outputting the first corrected data to the error correction section.

10-12. (canceled)
